(19) United States
(12) Patent Application Publication
(10) Pub. No.: US 2003/0002267 A1
(43) Pub. Date: Jan. 2, 2003

(54) I/O interface structure

(76) Inventors: Frank E. Mantz, Hawthorne, CA (US); Glen E. Roeters, Huntington Beach, CA (US)

Correspondence Address: STETINA BRUNDA GARRED & BRUCKER, 75 ENTERPRISE, SUITE 250, ALISO VIEJO, CA, 92656, US

(21) Appl. No.: 10/160,857

(22) Filed: Jun. 3, 2002

Related U.S. Application Data
(60) Provisional application No. 60/298,371, filed on Jun. 15, 2001.

(51) Int. Cl. H05K 7/10

(52) U.S. Cl. 361/767

(57) ABSTRACT

A chip stack comprising at least two chip packages. Each of the chip packages comprises a packaged chip including a body defining an opposed pair of sides and having a plurality of leads extending outwardly from each of the opposed sides thereof. Each chip package further comprises a pair of rails which extend along respective ones of the opposed sides of the body. Each of the rails defines opposed top and bottom surfaces and includes top inner and outer pads disposed on the top surface and bottom inner and outer pads disposed on the bottom surface. A plurality of conductive bumps are formed on respective ones of the top outer pads of each of the rails of one of the chip packages. In the chip stack, the chip packages are electrically connected to each other via the electrical connection of the leads of the packaged chip of one of the chip packages to respective ones of the bottom inner pads of the rails of the remaining one of the chip packages which include the conductive bumps formed on respective ones of the top outer pads thereof.

### CROSS-REFERENCE TO RELATED APPLICATIONS

This application claims the benefit of U.S. Provisional Application No. 60/298,371, filed Jun. 15, 2001.

### STATEMENT RE: FEDERALLY SPONSORED RESEARCH/DEVELOPMENT

(Not Applicable)

### BACKGROUND OF THE INVENTION

The present invention relates generally to chip stacks, and more particularly to a chip stack which is uniquely configured to provide a JEDEC Standard TSOP II 66 interface footprint combined with a fine pitch Ball Grid Array (BGA) “bump” to increase I/O interconnection capability.

As is currently known in the art, packaged components are often stacked using a variety of approaches. In all of the approaches to date, the concept has been for the end user to mount the stacks on the surface of a solid board such as a printed circuit board (PCB). More particularly, one of the most commonly used techniques to increase memory capacity is the stacking of memory devices into a vertical chip stack, sometimes referred to as 3D packaging or Z-Stacking. In the Z-Stacking process, from two to as many as eight memory devices or other integrated circuit (IC) chips are interconnected in a single component (i.e., a chip stack) which is mountable to the “footprint” typically used for a single packaged device such as a packaged chip. The Z-Stacking process has been found to be volumetrically efficient, with packaged chips in TSOP (thin small outline package) or LCC (leadless chip carrier) form generally being considered to be the easiest to use in relation thereto. Though bare dies may also be used in the Z-Stacking process, such use tends to make the stacking process more complex and not well suited to automation.

With particular regard to chip stacks formed by stacking TSOP packaged chips, the typical interface footprint included on a PCB to accommodate such a chip stack is commonly referred to as a JEDEC Standard TSOP II 66 interface footprint. However, because this particular interface footprint has a prescribed, limited number of I/O interconnection points, it is often desirable to provide a secondary footprint of additional I/O interconnection points on the PCB or other substrate adjacent to such primary interface footprint. One deficiency of chip stacks known in the prior art is the absence of any structures which are particularly adapted to facilitate the appropriate electrical connection of the chip stack to such secondary footprint. The present invention addresses this shortcoming by providing a chip stack providing a JEDEC Standard TSOP II 66 interface footprint combined with a fine pitch Ball Grid Array (BGA) “bump” specifically adapted for interface to the secondary footprint.

### BRIEF SUMMARY OF THE INVENTION

In accordance with the present invention, there is provided a chip stack comprising at least two chip packages. Each of the chip packages comprises a packaged chip including a body defining an opposed pair of sides and having a plurality of leads extending outwardly from each of the opposed sides thereof. Each chip package further comprises a pair of rails which extend along respective ones of the opposed sides of the body. Each of the rails defines opposed top and bottom surfaces and includes top inner and outer pads disposed on the top surface and bottom inner and outer pads disposed on the bottom surface. A plurality of conductive bumps are formed on respective ones of the top outer pads of each of the rails of one of the chip packages. In the chip stack, the chip packages are electrically connected to each other via the electrical connection of the leads of the packaged chip of one of the chip packages to respective ones of the bottom inner pads of the rails of the remaining one of the chip packages which include the conductive bumps formed on respective ones of the top outer pads thereof.

In the chip stack of the present invention, each of the top inner pads and each of the rails is electrically connected to a respective one of the bottom inner pads thereof. Similarly, each of the top outer pads of each of the rails is electrically connected to a respective one of the bottom outer pads thereof. At least one of the top outer pads of at least one of the rails of one of the chip packages is electrically connected to a respective one of the bottom outer pads of at least one of the rails of the remaining one of the chip packages via a solder column which may be fabricated from a noneutectic soldering material. The solder column(s) may be electrically insulated from the top inner pads and the bottom inner pads of each of the rails, or may alternatively be electrically connected to at least one of the top and bottom inner pads of at least one of the rails.

### BRIEF DESCRIPTION OF THE DRAWINGS

These, as well as other features of the present invention, will become more apparent upon reference to the drawings wherein:

FIG. 1 is a top plan view of the chip stack of the present invention;

FIG. 2 is a partial cross-sectional view taken along line B-B of FIG. 1; and

FIG. 3 is an enlarged view of the encircled region B shown in FIG. 1.

### DETAILED DESCRIPTION OF THE INVENTION

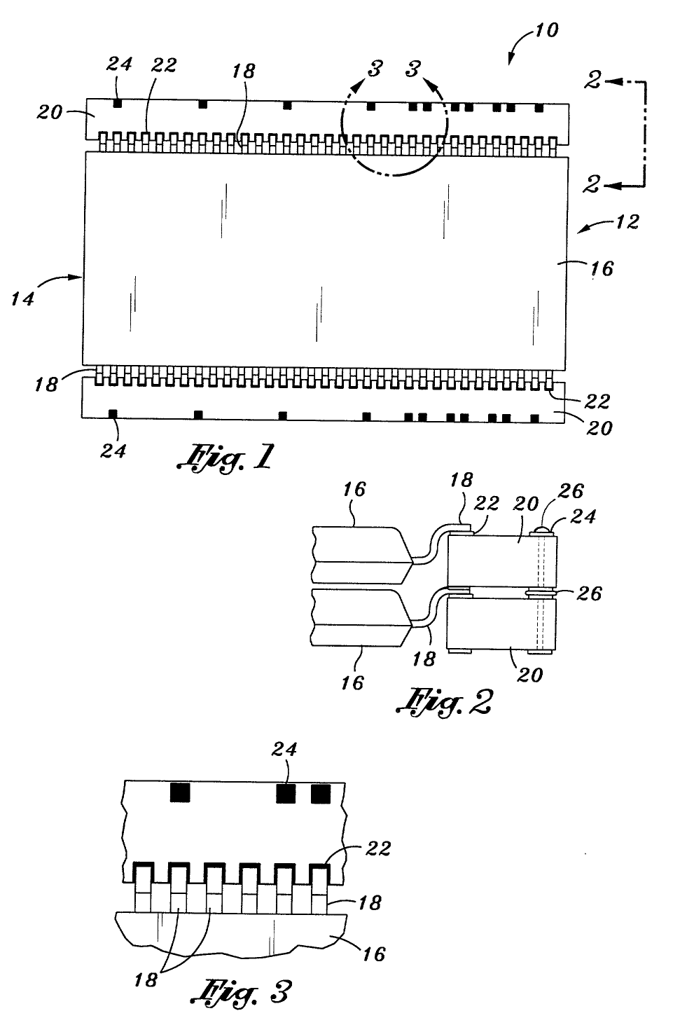

Referring now to FIGS. 1-3, the present invention is directed to a chip stack 10. The chip stack 10 comprises at least two (2) identically configured chip packages 12 which are stacked upon and electrically connected to each other in a manner which will be described in more detail below. Each of the chip packages 12 comprises a leaded packaged chip 14. As shown in FIGS. 1-3, the packaged chip 14 is a TSOP (thin small outline package) device including a rectangularly configured body 16 defining generally planar top and bottom surfaces, and opposed pairs of longitudinal and lateral sides. Extending from each of the longitudinal sides of the body 16 are a plurality of conductive leads 18 which, as seen in FIG. 2, each preferably have a gull-wing configuration.

In addition to the packaged chip 14, each of the chip packages 12 comprises a pair of elongate, rectangularly configured substrates or rails 20 which extend along respective ones of the longitudinal sides of the body 16 in spaced relation thereto. The rails 20 each define opposed, generally planar top and bottom surfaces. Disposed on the top surface of each of the rails 20 are a multiplicity of top inner conductive pads 22 which extend linearly in spaced relation to each other. Similarly, disposed on the bottom surface of each of the rails 20 are a multiplicity of bottom inner conductive pads which are arranged in the same pattern as and are preferably aligned with respective ones of the top inner conductive pads 22 of the same rail 20. In this regard, the top inner conductive pads 22 of each rail 20 are electrically connected to respective ones of the corresponding bottom inner conductive pads of the same rail 20 through the use of vias which extend through the rail 20 or, alternatively, conductive traces which extend exteriorly about the inner surface thereof.

In addition to the top inner conductive pads 22, each of the rails 20 of each chip package 12 includes a plurality of top outer conductive pads 24 which also extend linearly in spaced relation to each other. Disposed on the bottom surface of each rail 20 is a plurality of bottom outer conductive pads which are arranged in the same pattern as and are preferably aligned with respective ones of the top outer conductive pads 24 of the same rail 20. In this regard, the top outer conductive pads 24 of each rail are electrically connected to respective ones of the bottom outer conductive pads of the same rail 20 through the use of either vias or conductive traces which extend exteriorly about the outer surface of the rail 20.

In assembling each of the chip packages 12 of the chip stack 10, the leads 18 of each packaged chip 14 are electrically connected to respective ones of the top inner conductive pads 22 of a corresponding pair of rails 20. Such electrical connection is preferably accomplished through the use of Sn96 non-eutectic solder. As seen in FIG. 2, the assembly of the chip stack 10 is thereafter accomplished by stacking and electrically connecting the chip packages 12 to each other. When stacked, the leads 18 of one of the packaged chips 14 are captured or sandwiched between the rails 20 of the chip packages 12. More particularly, the leads 18 of one of the packaged chips 14, in addition to being electrically connected to respective ones of the top inner connective pads 22 of the corresponding pair of rails 20, are also electrically connected to respective ones of the bottom inner conductive pads of the rails 20 of the other chip package 12 within the chip stack 10. Again, such electrical connection is preferably accomplished through the use of Sn96 non-eutectic solder.

As further seen in FIG. 2, the top outer conductive pads 24 of the rails 20 of one of the chip packages 12 are themselves electrically connected to respective ones of the bottom outer conductive pads of the rails 20 of the remaining chip package 12 through the use of a solder bump 26, itself preferably formed of Sn96 non-eutectic solder. A solder bump 26 is also formed on each of the top outer conductive pads 24 of one of the chip packages 12, and more particularly on that chip package 12 wherein the leads 18 of the corresponding packaged chip 14 are not captured between the rails 20. Such solder bump(s) 26 is/are preferably formed having a height which is substantially coplanar to the distal ends of the leads 18 of the corresponding packaged chip 14 electrically connected to the rails 20.

In the chip stack 10, the leads 18 of the packaged chip 14 which are exposed define a JEDEC Standard TSOP II 66 interface footprint. The adjacent exposed bumps 26 themselves create a supplemental fine pitch Ball Grid Array (BGA) footprint. These primary and secondary footprints can be used to establish a desired electrical connection between the chip stack 10 and a PCB or other substrate including corresponding primary and secondary interface footprints as described above. The electrical interconnection between the secondary fine pitch Ball Grid Array interface footprint can be used to establish a discreet electrical connection to any lead 18 of any one of packaged chips 14, bypassing the other packaged chip(s) 14 in the chip stack 10. In this regard, the top outer conductive pads 24 and/or bottom outer conductive pads of any chip package 12 can be electrically connected to one or more of the top inner conductive pads 22 and/or one or more of the bottom inner conductive pads of another chip package 12 within the chip stack 10 through the use of exterior conductive traces or internal vias. As an alternative to being used to establish a discreet electrical connection to one of the packaged chips 14, the electrical interconnection achieved by the solder bumps 26 can also be used to establish a discreet electrical connection to a component separate from the chip stack 10 via the chip stack 10.

1. A chip stack comprising:
at least two chip packages, each comprising:
a packaged chip including a body defining an opposed pair of sides and having a plurality of leads extending outwardly from each of the opposed sides thereof; and
a pair of rails which extend along respective ones of the opposed sides of the body, each of the rails defining opposed top and bottom surfaces and including top inner and outer pads disposed on the top surface and bottom inner and outer pads disposed on the bottom surface, the leads of the packaged chip being electrically connected to respective ones of the top inner pads of each of the rails;
a plurality of conductive bumps formed on respective ones of the top outer pads of each of the rails of one of the chip packages;
the chip packages being electrically connected to each other via the electrical connection of the leads of the packaged chip of one of the chip packages to respective ones of the bottom inner pads of the rails of the remaining one of the chip packages which include the conductive bumps formed on respective ones of the top outer pads thereof.

2. The chip stack of claim 1 wherein the conductive bumps disposed on the top outer pads of each of the rails of the remaining one of the chip packages are each formed to have a height which is substantially coplanar to the leads of the packaged chip which are electrically connected to respective ones of the top inner pads of each of the rails of the remaining one of the chip packages.

3. The chip stack of claim 2 wherein:
the leads of the packaged chip electrically connected to the top inner pads of each of the rails of the remaining one of the chip packages are arranged to define a JEDEC Standard TSOP II interface footprint; and
the conductive bumps are arranged to create a supplemental fine pitch ball grid array footprint.

4. The chip stack of claim 1 wherein:
each of the top inner pads of each of the rails is electrically connected to a respective one of the bottom inner pads thereof; and
each of the top outer pads of each of the rails is electrically connected to a respective one of the bottom outer pads thereof.

5. The chip stack of claim 1 wherein at least one of the top outer pads of at least one of the rails of one of the chip packages is electrically connected to a respective one of the bottom outer pads of at least one of the rails of the remaining one of the chip packages via a solder column.

6. The chip stack of claim 5 wherein the solder column is fabricated from a noneutectic soldering material.

7. The chip stack of claim 5 wherein the solder column is electrically insulated from the top inner pads and the bottom inner pads of each of the rails.

8. The chip stack of claim 5 wherein the solder column is electrically connected to at least one of the top and bottom inner pads of at least one of the rails.

9. A method of fabricating a chip stack, comprising the steps of:
a) providing at least two chip packages, each of which comprises:
a packaged chip including a body defining opposed pairs of sides having a plurality of leads extending outwardly from each of the opposed sides thereof; and
a pair of rails which extend along respective ones of the opposed sides of the body, each of the rails defining opposed top and bottom surfaces and including top inner and outer pads disposed on the top surface and bottom inner and outer pads disposed on the bottom surface, the leads of the packaged chip being electrically connected to respective ones of the top inner pads of each of the rails;
b) forming a plurality of conductive bumps on respective ones of the top outer pads of each of the rails of one of the chip packages; and
c) electrically connecting the chip packages to each other via the electrical connection of the leads of the packaged chip of one of the chip packages to respective ones of the bottom inner pads of the rails of the remaining one of the chip packages which include the conductive bumps formed on respective ones of the top outer pads thereof.

10. The method of claim 9 wherein step (a) comprises providing chip packages wherein each of the top inner pads of each of the rails is electrically connected to a respective one of the bottom inner pads thereof, and each of the top outer pads of each of the rails is electrically connected to a respective one of the bottom outer pads thereof.

11. The method of claim 10 further comprising the step of:
d) electrically connecting at least one of the top outer pads of at least one of the rails of one of the chip packages to a respective one of the bottom outer pads of at least one of the rails of the remaining one of the chip packages via a solder column.

12. The method of claim 11 wherein step (d) comprises electrically insulating the solder column from the top inner pads and the bottom inner pads of each of the rails.

13. The method of claim 11 wherein step (d) comprises electrically connecting the solder column to at least one of the top and bottom inner pads of at least one of the rails.

14. The method of claim 9 wherein step (b) comprises forming each of the conductive bumps to have a height which is substantially coplanar to that of the leads electrically connected to respective ones of the top inner pads of each of the rails of the remaining one of the chip packages.

15. The method of claim 9 wherein step (c) comprises electrically connecting the chip packages to each other such that the leads of the packaged chip electrically connected to respective ones of the top inner pads of the remaining one of the chip packages are arranged to define a JEDEC Standard TSOP II interface footprint and the conductive bumps are arranged to create a supplemental fine pitch ball grid array footprint.
